(19) United States
(12) Patent Application Publication
(10) Pub. No.: US 2025/0393117 A1
(43) Pub. Date: Dec. 25, 2025

(54) INTEGRATION OF BGA PACKAGE ON PCB WITH REDUCED CROSSTALK

(71) Applicant: Marvell Asia Pte Ltd, Singapore (SG)

(72) Inventor: Ershad Shaik, Bangalore (IN)

(21) Appl. No.: 19/246,122

(22) Filed: Jun. 23, 2025

(30) Foreign Application Priority Data
Jun. 24, 2024 (IN) 202441048423

(51) Int. Cl. H05K 1/02; H05K 1/11; H05K 1/18

(52) U.S. Cl. CPC H05K 1/0216; H05K 1/115; H05K 1/181; H05K 2201/09227; H05K 2201/09518; H05K 2201/10159; H05K 2201/10734

(57) ABSTRACT

A device includes an electrical board including a plurality of ball grid arrays (BGA) groups. Each BGA group of the plurality of BGA groups includes its respective BGA balls connected to its respective vias configured to route electrical signals between an integrated circuit to the electrical board. Vias for two adjacent BGA group of the plurality of BGA groups connect to different layers of the plurality of layers of the electrical board.

### CROSS-REFERENCE TO RELATED APPLICATIONS

This application claims the benefit and priority to the Indian Patent Application number 202441048423 filed on Jun. 24, 2024, which is incorporated herein by reference in its entirety.

### BACKGROUND

Crosstalk (unwanted coupling of signals) in electronic devices has increased as data rates have increased in high-speed electronic devices. For example, in high-pin-density Ball Grid Array (BGA) packages, the endpoints are closely packed resulting in signal distortion and interference associated with the endpoints. In order to reduce crosstalk, some design the BGA with particular pin assignments to reduce proximity between an aggressor signal (signal causing unwanted noise or interference on proximate or other signals) and a victim signal (signal being impacted by unwanted noise or interference generated by an aggressor signal). Some BGA package designs ensure a well-distributed network of ground and power pins to manage signal current while others may shield BGA package or specific traces to reduce radiated interference. Unfortunately, most conventional approaches for reducing crosstalk require more complicated designs and increase costs.

The foregoing examples of the related art and limitations related therewith are intended to be illustrative and not exclusive. Other limitations of the related art will become apparent upon a reading of the specification and a study of the drawings.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 depicts an example of a top view for an electrical board with connections on BGA break-out region according to one aspect of the present embodiments.

FIG. 2 depicts an example of a side view for an electrical board in isometric view with connections on BGA break-out region according to one aspect of the present embodiments.

FIG. 3 depicts another example of an electrical board with connections on BGA break-out region according to one aspect of the present embodiments.

FIG. 4 depicts a performance of a through-hole via in comparison to variable-depth via according to one aspect of the present embodiments.

FIG. 5 depicts a system [with an electrical board with BGA connections] according to one aspect of the present embodiments.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Before various embodiments are described in greater detail, it should be understood that the embodiments are not limiting, as elements in such embodiments may vary. It should likewise be understood that a particular embodiment described and/or illustrated herein has elements which may be readily separated from the particular embodiment and optionally combined with any of several other embodiments or substituted for elements in any of several other embodiments described herein. It should also be understood that the terminology used herein is for the purpose of describing the certain concepts, and the terminology is not intended to be limiting. Unless defined otherwise, all technical and scientific terms used herein have the same meaning as commonly understood in the art to which the embodiments pertain.

As data rates for integrated circuits (ICs), such as a double data rate (DDR) memory, microprocessors, etc., increase, the need to pack BGA package signals more densely using high-pin-density BGAs increases. BGA is a type of surface mount package that can be put on a dual in-line or flat package used for integrated circuits. A BGA package typically has a plurality of BGA balls (each offering a point of external connection—in some instances these are solder balls) each with a via for routing electrical signals between the integrated circuit and the PCB/electrical board. Unfortunately, high-pin-density results in densely packed signals, and when signals are close to one another this increases crosstalk. Accordingly, it is desirable to reduce crosstalk (unwanted coupling of signals) in electronic devices, especially in light of ever increasing data rates.

According to some embodiments, a BGA package is designed such that each BGA group (e.g., BGA balls and vias) that are adjacent to one another connect to a different layer of the electronic board (e.g., printed circuit board (PCB)), thereby reducing crosstalk. It is appreciated that the layers are positioned in substantially parallel orientation with respect to the top surface of the PCB. BGA groups that are not adjacent to one another may connect to the same layer, if desired, without significantly causing crosstalk. It is appreciated that each BGA group may be associated with a byte of data (or channel). For example, each BGA ball may be associated with a bit within a byte. As such, the vias within the same BGA group (same byte) connect to the same layer. Since the neighboring BGA groups (associated with different bytes) connect to different layers, crosstalk between the neighboring BGA groups, and therefore the data in different bytes, is reduced.

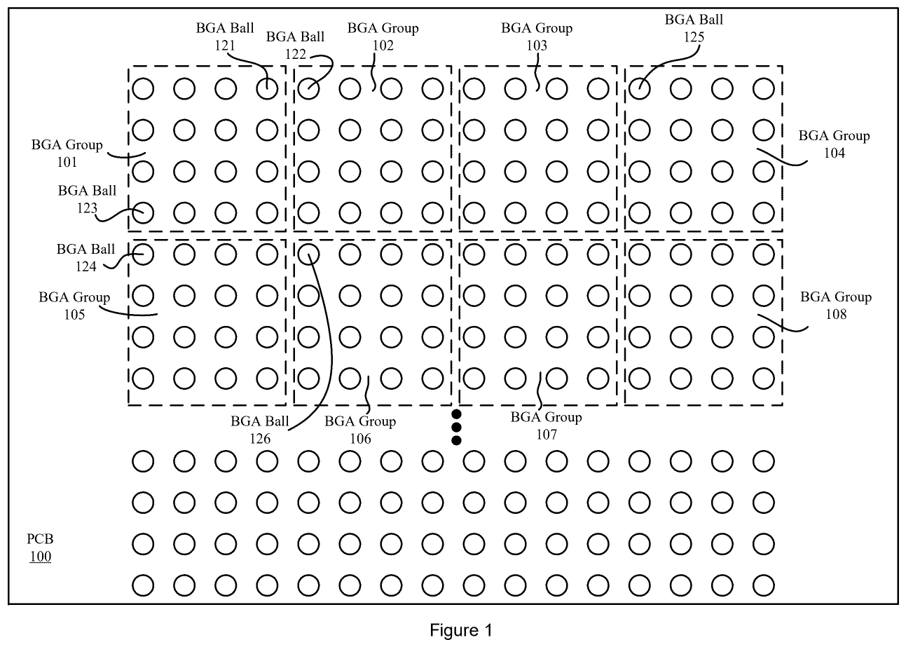

FIG. 1 depicts an example of a top view for an electrical board (e.g., PCB 100) with connections on ball grid array (BGA) break-out region according to one aspect of the present embodiments. The PCB 100 includes a plurality of BGA balls. The plurality of BGA balls may form a plurality of groups arranged in a plurality of rows and columns. For example, the first row of the PCB 100 may include BGA group 101 that may include 16 BGA balls arranged in a 4-row by 4-column structure. The BGA group 101 includes BGA balls 121 and 123. The neighboring (adjacent) BGA to the BGA group 101 is the BGA group 102 that also includes 16 BGA balls arranged in a 4-row by 4 column structure. The BGA group 102 includes a BGA ball 122. The neighboring (adjacent) BGA to the BGA group 102 is the BGA group 103 that also includes 16 BGA balls arranged in a 4-row by 4 column structure. The neighboring (adjacent) BGA to the BGA group 103 is the BGA group 104 that also includes 16 BGA balls arranged in a 4-row by 4 column structure. The BGA group 104 includes a BGA ball 125.

The second row of the PCB 100 may include BGA groups 105-108. The BGA group 105 is a neighboring (adjacent) BGA to that of BGA groups 101 and 102 because the BGA group 105 is positioned immediately below the BGA group 101 and it is further diagonally positioned with respect to the BGA group 102. The BGA group 105 may include BGA ball 124. The BGA group 106 is a neighboring (adjacent) BGA to that of BGA groups 102-103 and 105 and 107 for similar reasons. The BGA group 106 includes a BGA ball 126. The BGA group 107 is a neighboring (adjacent) BGA to that of BGA groups 106, 108, and 102-104 for similar reasons. The BGA group 108 is a neighboring (adjacent) BGA to that of BGA group 107, and 103-104 for similar reasons.

It is appreciated that any number of BGA groups may be present and the number of BGA groups shown is for illustrative purposes only and should not be construed as limiting the scope of the embodiments. It is appreciated that each BGA group may include a subset of BGA balls that are connected to a given layer of the PCB using a subset of vias. The number of BGA connections within each group is for illustration purposes and should not be construed as limiting the scope of the embodiments. Furthermore, the arrangement within each BGA group (e.g., 4-rows by 4-columns) is for illustrative purposes only and should not be construed as limiting the scope of the embodiments. For example, in some embodiments the BGA connections may be arranged in a 3-rows by 3-columns structure. Moreover, it is appreciated that the BGA groups are shown with the same structure for illustrative purposes and should not be construed as limiting the scope of the embodiments. For example, in one embodiment, the BGA group 101 may include 16 BGA connections arranged in a 4-row by 4-column structure while the BGA group 102 may include 9 BGA connections arranged in a 3-row by 3-column structure, etc.

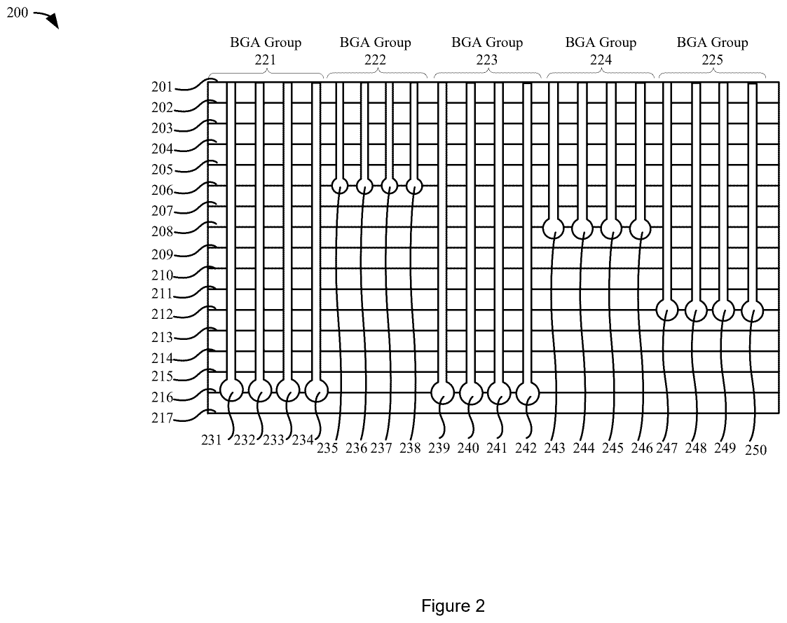

According to some embodiments, the neighboring BGA groups connect to a layer of the PCB 100 that are different from one another (described in greater detail in FIG. 2 below). The BGA balls of the neighboring BGA groups connecting to a different layer of the PCB 100 reduces crosstalk at the breakout (at the fanout point) on the chip when routing an electrical signal between the IC and the PCB. In other words, each BGA group has a via structure, e.g., shallow versus deep, that is different from its neighboring (adjacent) BGA group. Accordingly, different via structures are incorporated such that different bytes of data at the BGA fanout at a different layer (for adjacent BGA groups). Thus, the capacitive and inductive attributes of crosstalk are mitigated by limiting the coupling length and separation in the BGA pin field region.

FIG. 2 depicts an example of a side view for an electrical board 200 in isometric view with connections on BGA break-out region according to one aspect of the present embodiments. The electrical board 200 may be a PCB in one nonlimiting example includes a plurality of layers 201-217. The layers 201-217 are disposed on top of one another (stacked). It is appreciated that additional layers may be disposed between the layers 201-217 (not shown) that serve purposes separate from that of layers 201-217. For example, the layers 201-217 may or may not be in direct contact with one another. It is appreciated that layers 201-217 are positioned in substantially parallel orientation (e.g., shown horizontally in FIG. 2) with respect to the top surface of the electrical board 200. The number of layers that are shown is for illustrative purposes only and should not be construed as limiting the scope of the embodiments.

The PCB includes BGA groups 221-225 (e.g., first rows). The BGA group 221 includes a plurality of vias 231-234 that connect the BGA balls within the BGA group 221 from the top surface of the PCB to layer 216 of the PCB. The neighboring (adjacent) BGA group 222 to that of BGA group 221 includes a plurality of vias 235-238 that connect the BGA balls within the BGA group 222 from the top surface of the PCB to layer 206 of the PCB. Since the adjacent BGA groups (e.g., BGA groups 221 and 222) connect to different layers (e.g., layers 216 and 206 respectively), the crosstalk between signals in BGA groups 221 and 222 is reduced.

The BGA group 223 includes a plurality of vias 239-242 that connect the BGA balls within the BGA group 223 from the top surface of the PCB to layer 216 of the PCB. Since the adjacent BGA groups (e.g., BGA groups 223 and 222) connect to different layers (e.g., layers 216 and 206 respectively), the crosstalk between signals in BGA groups 223 and 222 is reduced. It is appreciated that the vias 239-242 of BGA group 223 may connect to the same layer (e.g., layer 216) as that of BGA group 221 since the BGA groups 221 and 223 are not adjacent to one another, with minimal impact on crosstalk. It is appreciated that the vias 239-242 may connect to any layer other than layer 206 since the vias 235-238 of BGA group 222 are connected to layer 206.

The BGA group 224 includes a plurality of vias 243-246 that connect the BGA balls within the BGA group 224 from the top surface of the PCB to layer 208 of the PCB. Since the adjacent BGA groups (e.g., BGA groups 224 and 223) connect to different layers (e.g., layers 208 and 216 respectively), the crosstalk between signals in BGA groups 223 and 224 is reduced. It is appreciated that the vias 243-246 of BGA group 224 connect to the same layer (e.g., layer 206) as that of BGA group 222 since the BGA groups 224 and 222 are not adjacent to one another, with minimal impact on crosstalk. It is appreciated that the vias 243-246 may be configured to connect to any layer other than layer 216 since the vias 239-242 of BGA group 223 are connected to layer 216.

The BGA group 225 includes a plurality of vias 247-250 that connect the BGA balls within the BGA group 225 from the top surface of the PCB to layer 212 of the PCB. Since the adjacent BGA groups (e.g., BGA groups 224 and 225) connect to different layers (e.g., layers 208 and 212 respectively), the crosstalk between signals in BGA groups 224 and 225 is reduced. It is appreciated that the vias 247-250 of BGA group 225 may be configured to connect to any layer other than layer 208, e.g., the same layer (e.g., layer 206 or 216) as that of BGA groups 221-223 since the BGA groups 225 and 221-223 are not adjacent to one another, with minimal impact on crosstalk. It is appreciated that the vias 243-246 may be configured to connect to any layer other than layer 216 since the vias 239-242 of BGA group 223 are connected to layer 216.

Accordingly, each neighboring (adjacent) BGA group connects the BGA ball of that group to a layer that is different from its adjacent BGA group, thereby reducing crosstalk. In other words, the vias within neighboring (adjacent) BGA groups have variable depths to reduce crosstalk.

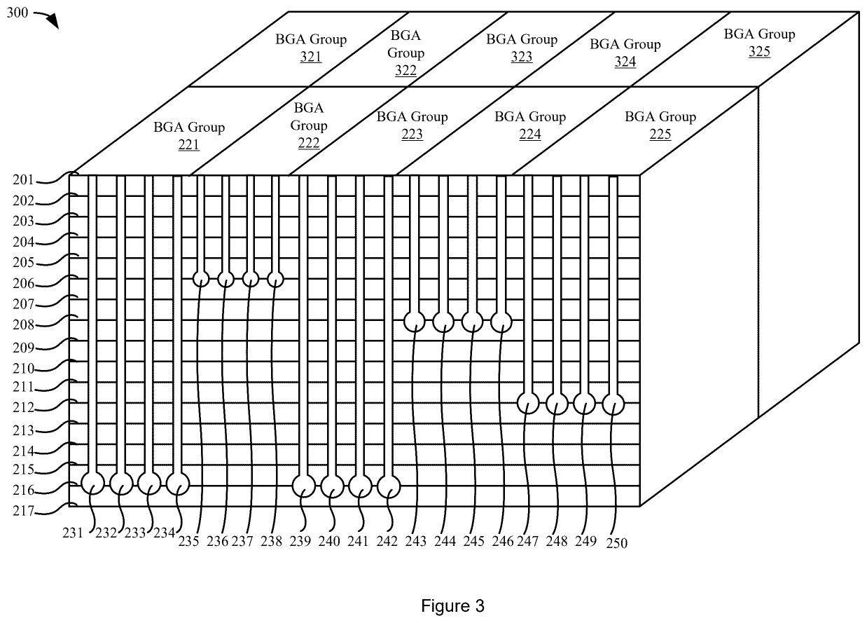

FIG. 3 depicts another example of an electrical board 300 with connection on BGA break-out region according to one aspect of the present embodiments. FIG. 3 is similar to that of FIG. 2. In FIG. 3, the PCB includes a second row of BGA groups, e.g., BGA groups 321-325. The BGA group 321 is adjacent to BGA groups 221, 322, and 222. The BGA group 322 is adjacent to BGA groups 321, 323, and 221, 222, 223. The BGA group 323 is adjacent to BGA groups 322, 324, and 222, 223, 224. The BGA group 324 is adjacent to BGA groups 323, 325, and 223, 224, 225. The BGA group 325 is adjacent to BGA groups 324 and 224, 225.

It is appreciated that the vias of BGA groups that are adjacent to one another connect the BGA balls to a different layer of the PCB, as described above, to reduce crosstalk. However, nonadjacent (non-neighbors) BGA groups may connect the BGA balls to the same layer of the PCB, if desired. As illustrated, at the breakout region, the adjacent BGA groups are fanouts at different layers of the PCB to reduce crosstalk.

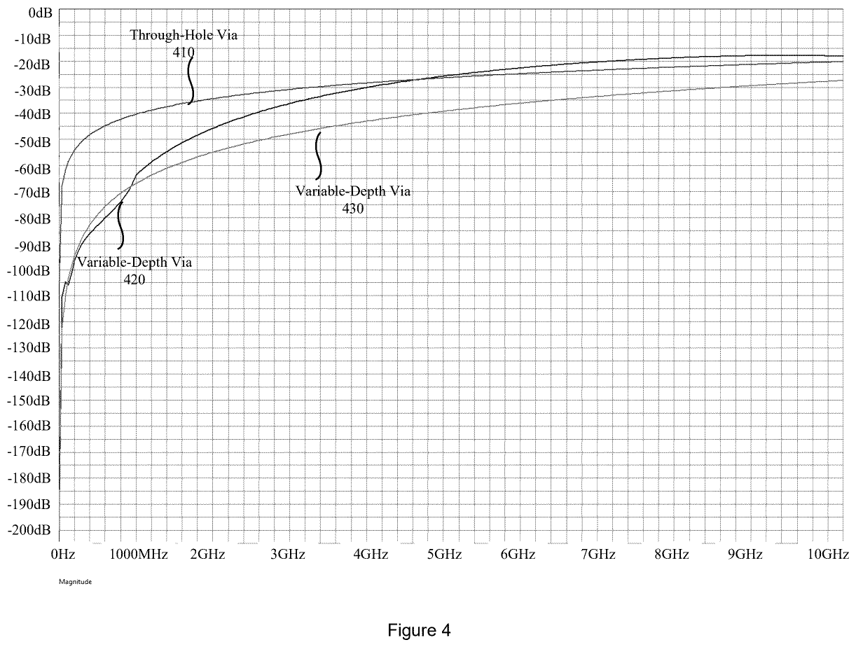

FIG. 4 depicts a performance of a through-hole via in comparison to variable-depth via according to one aspect of the present embodiments. The performance (crosstalk) associated with through-hole via 410 (conventional system) is compared to variable-depth vias 420 and 430 as data rate increases. As illustrated, having a different depth via for the neighboring (adjacent) BGA groups reduces crosstalk in comparison to the conventional system where the depth of the vias is the same (i.e., through-hole via 410). It is appreciated that the horizontal axis (x-axis) is associated with frequency while the vertical axis (y-axis) is associated with loss (noise) in decibel (dB).

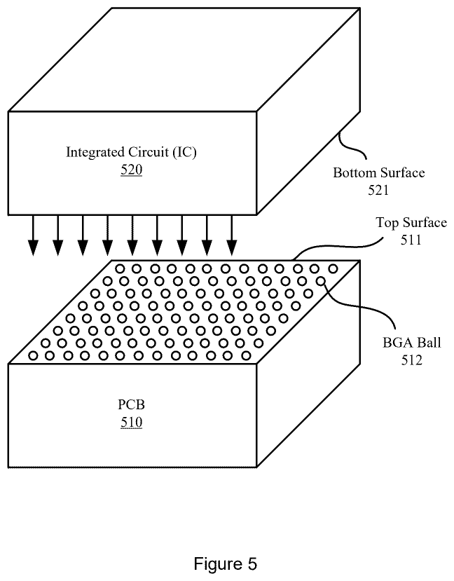

FIG. 5 depicts a system according to one aspect of the present embodiments. In one nonlimiting example, the PCB 510 may include a plurality of BGA balls 512 positioned on a top layer 511 of the PCB 510. The BGA balls 512 may be arranged into BGA groups, as described in FIGS. 1-3 where the adjacent BGA groups connect their respective BGA balls to a different layer within the PCB 510. The IC 520 may be a microcontroller, processor, DDR memory, etc., and may have a bottom layer 521 that also includes BGA balls for connecting to the top layer 511 of the PCB 510. The IC 520 may also include a plurality of vias where the neighboring BGAs connect their respective BGA balls to a different layer within the IC 520 (similar to the PCB 510). As such, electrical signals can be routed between the IC 520 and the PCB 510 while crosstalk between BGA groups (adjacent BGA groups) is reduced (on one or more of the IC 510 and PCB 510).

The foregoing description of various embodiments of the claimed subject matter has been provided for the purposes of illustration and description. It is not intended to be exhaustive or to limit the claimed subject matter to the precise forms disclosed. Many modifications and variations will be apparent to the practitioner skilled in the art. Embodiments were chosen and described in order to best describe the principles of the invention and its practical application, thereby enabling others skilled in the relevant art to understand the claimed subject matter, the various embodiments and the various modifications that are suited to the particular use contemplated.

What is claimed is:

1. A device configured to reduce crosstalk across signals routed within the device, the device comprising:
an electrical board including a plurality of layers, wherein adjacent layers of the plurality of layers are stacked on top of one another;
a plurality of ball grid array (BGA) balls formed on a top layer of the electrical board and configured to make electrical contact with an integrated circuit device; and
a plurality of vias associated with the plurality of BGA balls, wherein the plurality of vias is configured to route electrical signal between the electrical board and the integrated circuit device using electrical connections to one another using the plurality of BGA balls,
wherein a first subset of BGA balls of the plurality of BGA balls connected to a first subset of vias of the plurality of vias forms a first BGA group,
wherein a second subset of BGA balls of the plurality of BGA balls connected to a second subset of vias of the plurality of vias forms a second BGA group,
wherein the first BGA group and the second BGA group are adjacent to one another on the top layer of the electrical board,
and wherein the first subset of vias connects to a layer of the plurality of layers and wherein the second subset of vias connects to another layer of the plurality of layers, wherein the layer is different from the another layer.

2. The device of claim 1, wherein the electrical board is a printed circuitry board (PCB).

3. The device of claim 1, wherein the integrated circuit device is a double data rate (DDR) memory.

4. The device of claim 1, wherein a third subset of BGA balls of the plurality of BGA balls connected to a third subset of vias of the plurality of vias form a third BGA group, wherein the third BGA group is not adjacent to the first BGA group.

5. The device of claim 4, wherein the third subset of vias connects to the layer of the plurality of layers.

6. The device of claim 4, wherein the third BGA group is adjacent to the second BGA group.

7. The device of claim 1, wherein the first BGA group is associated with one channel of data and the second BGA group is associated with another channel of data, wherein crosstalk associated with the first BGA group and the second BGA group is reduced in comparison to if the first subset of vias and the second subset of vias connect to a same layer of the plurality of layers.

8. A device configured to reduce crosstalk across signals routed within the device, the device comprising:
an electrical board including a plurality of ball grid arrays (BGA) groups,
wherein each BGA group of the plurality of BGA groups includes its respective BGA balls connected to its respective vias configured to route electrical signals within the electrical board,
wherein vias for two adjacent BGA group of the plurality of BGA groups connect to different layers of the plurality of layers of the electrical board.

9. The device of claim 8, wherein the electrical board is a printed circuitry board (PCB).

10. The device of claim 8, wherein the integrated circuit device is a double data rate (DDR) memory.

11. The device of claim 8, wherein at least two BGA groups that are not adjacent to one another connect to a same layer of the plurality of layers of the electrical board.

12. The device of claim 8, wherein each BGA group is associated with a different data channel, and wherein crosstalk associated with the two adjacent BGA group is reduced in comparison to the two adjacent BGA group connecting to a same layer of the plurality of layers.

13. The system of claim 8, wherein a number of layers of the plurality of layers ranges from 10-24 layers.

14. A system configured to reduce crosstalk across signals routed within the device, the system comprising:
an electrical board including a plurality of ball grid arrays (BGA) groups,
wherein each BGA group of the plurality of BGA groups includes its respective BGA balls connected to its respective vias,
wherein vias for two adjacent BGA group of the plurality of BGA groups connect to different layers of the plurality of layers of the electrical board; and
an integrated circuit coupled to the electrical board, wherein the each BGA group is configured to route electrical signals between the integrated circuit and the electrical board.

15. The system of claim 14, wherein the electrical board is a printed circuitry board (PCB).

16. The system of claim 14, wherein the integrated circuit device is a double data rate (DDR) memory.

17. The system of claim 14, wherein at least two BGA groups that are not adjacent to one another connect to a same layer of the plurality of layers of the electrical board.

18. The system of claim 14, wherein each BGA group is associated with a different data channel, and wherein crosstalk associated with the two adjacent BGA group is reduced in comparison to the two adjacent BGA group connecting to a same layer of the plurality of layers.

19. The system of claim 8, wherein a number of layers of the plurality of layers ranges from 10-24 layers.
